(19) United States
(12) Patent Application Publication
(10) Pub. No.: US 2019/0080039 A1
(43) Pub. Date: Mar. 14, 2019

(54) INTEGRATED CIRCUIT, SCAN SHIFT CONTROL METHOD, AND CIRCUIT DESIGN METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Masaki OISO, Tokyo (JP)

(73) Assignees: KABUSHIKI KAISHA TOSHIBA, Tokyo (JP); TOSHIBA ELECTRONIC DEVICES & STORAGE CORPORATION, , Tokyo (JP)

(21) Appl. No.: 15/889,537

(22) Filed: Feb. 6, 2018

(30) Foreign Application Priority Data
Sep. 12, 2017 (JP) 2017-174947

(51) Int. Cl. G06F 17/50; H03K 5/135; H03K 5/133

(52) U.S. Cl. CPC G06F 17/5081; G06F 2217/62; H03K 5/133; H03K 5/135

(57) ABSTRACT

According to one embodiment, there is provided an integrated circuit including a plurality of flip-flops, and a control circuit that repeats a control that makes each of the flip-flops perform input and output operation in a predetermined group order with a time difference in a state where the flip-flops are connected in a scan chain and grouped.

### CROSS-REFERENCE TO RELATED APPLICATIONS

This application is based upon and claims the benefit of priority from Japanese Patent Application No. 2017-174947, filed Sep. 12, 2017, the entire contents of which are incorporated herein by reference.

### FIELD

Embodiments described herein relate generally to an integrated circuit, a scan shift control method, and a circuit design method.

### BACKGROUND

There is a scan test, as one of a design-for-testability (DFT) technology of LSI. This scan test has been known as a method for detecting a defect in a system combinational circuit included in an LSI.

When the scan test is conducted, individual flip-flops in the circuit are serially connected, and a path (namely, scan chain) is formed so that the flip-flop can be controlled and observed from an external I/O terminal of the LSI. Since the individual flip-flops connected by this scan chain are directly connected to each other, a data hold time violation may occur at the time of data transmission.

### BRIEF DESCRIPTION OF THE DRAWINGS

FIG. 1 is a schematic diagram showing an example of a schematic configuration when conducting a scan test of a semiconductor integrated circuit according to a first embodiment;

FIG. 2 is a schematic diagram for explaining an example of a circuit configuration and clock control when conducting the scan test of the semiconductor integrated circuit according to the first embodiment;

FIG. 3 is a circuit diagram showing an example of a configuration of a control circuit according to the first embodiment;

FIG. 4 is a schematic diagram for explaining an example of scan shift operation according to the first embodiment;

FIG. 5 is a timing chart showing an example of the scan shift operation according to the first embodiment;

FIG. 6 is a schematic diagram for explaining an example of a circuit configuration and clock control when conducting the scan test of a semiconductor integrated circuit according to a second embodiment;

FIG. 7 is a circuit diagram showing an example of a configuration of a control circuit according to the second embodiment;

FIG. 8 is a schematic diagram for explaining an example of scan shift operation according to the second embodiment;

FIG. 9 is a timing chart showing an example of the scan shift operation according to the second embodiment;

FIG. 10 is a flowchart showing the design procedure of a semiconductor integrated circuit according to a third embodiment; and

FIG. 11 is a schematic diagram showing processing contents of individual steps shown in FIG. 10.

### DETAILED DESCRIPTION

Embodiments will be described below with reference to the drawings.

In general, according to one embodiment, there is provided an integrated circuit including a plurality of flip-flops, and a control circuit that repeats a control that makes each of the flip-flops perform input and output operation in a predetermined group order with a time difference in a state where the flip-flops are connected in a scan chain and grouped.

### First Embodiment

First, the first embodiment will be described.

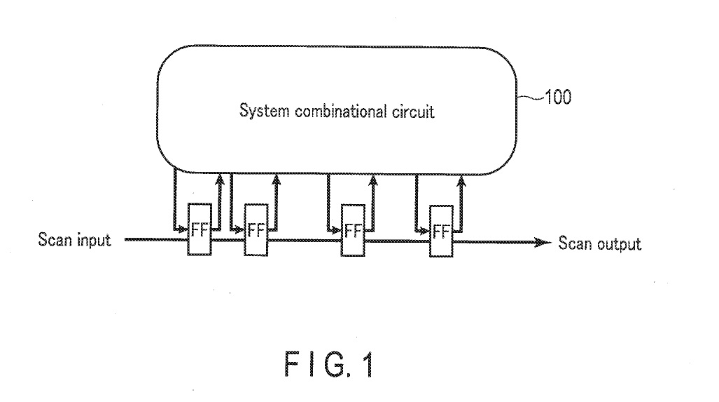

FIG. 1 is a schematic diagram showing an example of a schematic configuration when conducting a scan test of a semiconductor integrated circuit according to the first embodiment. FIG. 1 also applies to a second embodiment to be described later.

As shown in FIG. 1, the semiconductor integrated circuit is provided with a system combinational circuit 100 and a plurality of flip-flops (FF).

A path for inputting and outputting data is provided between the system combinational circuit 100 and the individual flip-flops. This route is used in an ordinary operation mode in which ordinary operation is performed.

In a scan mode in which scanning is performed, a path (namely, scan chain) for serially connecting the individual flip-flops is formed. During the scan mode, data of a test pattern is input from a scan input terminal of the semiconductor integrated circuit, sequentially passes through the individual flip-flops through the scan chain, and then is output from a scan output terminal of the semiconductor integrated circuit.

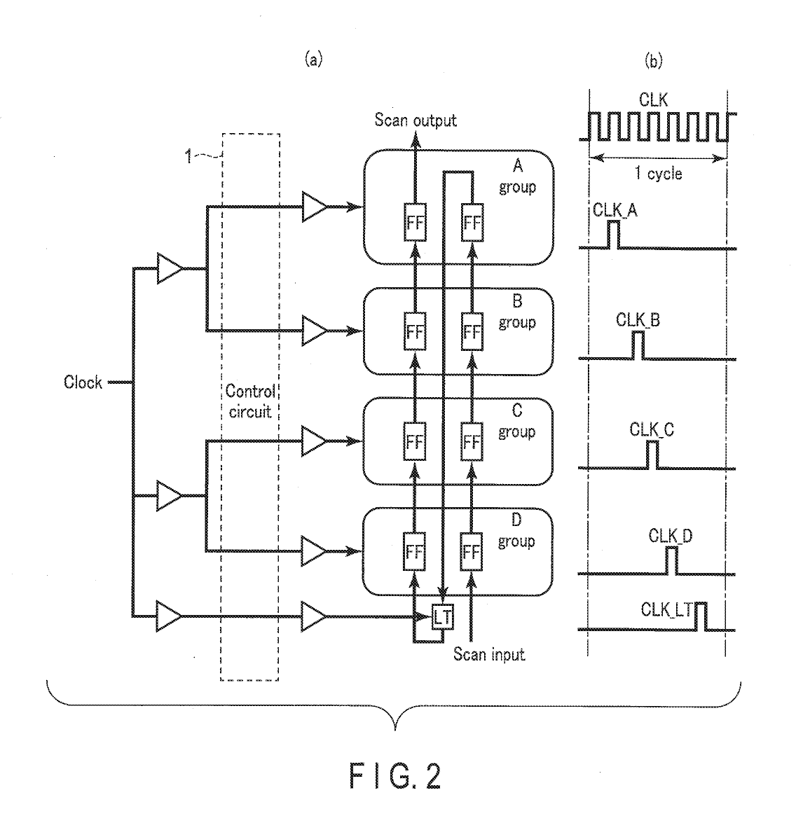

FIG. 2 is a schematic diagram for explaining an example of a circuit configuration and clock control when conducting the scan test of the semiconductor integrated circuit according to the first embodiment.

As shown in (a) of FIG. 2, the flip-flops provided in the semiconductor integrated circuit are grouped into four groups, for example, an A group, a B group, a C group, and a D group.

The semiconductor integrated circuit is provided with a control circuit 1 that performs scan shift control that does not cause violation of the hold time of transmission data.

The control circuit 1 has the following function. That is, in a state where the flip-flops are serially connected in the scan chain and grouped, the control circuit 1 repeatedly performs processing of generating and outputting rectangular wave signals (for example, pulse-shaped signals) having different operation timings with respect to individual groups based on a clock serving as a reference and thereby repeats a control that makes each flip-flop perform input and output operation with a time difference (a time difference for guaranteeing that hold time violation does not occur) in a predetermined group order (in the order of the A group, the B group, the C group, and the D group in this example) in units of groups.

In addition to the flip-flops, the semiconductor integrated circuit further includes a data holding circuit. In the present embodiment, the data holding circuit is realized by a latch circuit LT that holds data of 1 bit. However, it is not limited thereto. Alternatively, a flip-flop may be adopted. Since the latch circuit LT is smaller than the flip-flop, less installation space is required.

The latch circuit LT temporarily holds data transferred between specific groups (data transferred from the A group to the D group in this example).

As described above, according to the present embodiment, since the latch circuit LT is provided in addition to the flip-flops, the control circuit 1 repeats a control that makes each flip-flop sequentially perform input and output operation with a time difference in a predetermined group order (in the order of the A group, the B group, the C group, and the D group in this example) in units of groups and then further makes the latch circuit LT perform input operation with a time difference.

In the first embodiment, it is assumed that the latch circuit LT is configured not to belong to any group of the A group, the B group, the C group, and the D group described above. In this case, the control circuit 1 needs to supply rectangular wave signals, having different operation timings from the A group, the B group, the C group, and the D group, to the latch circuit LT. Thus, the control circuit 1 supplies the rectangular wave signals to each group in a predetermined group order (in the order of the A group, the B group, the C group, and the D group in this example) with a time difference, and then further supplies the rectangular wave signals to the latch circuit LT with a time difference.

As a result, each flip-flop performs the input and output operation in response to a first edge (a rising edge in this example) of the rectangular wave supplied from the control circuit 1. On the other hand, the latch circuit LT performs the input operation in response to the first edge (the rising edge in this example) of the rectangular wave supplied from the control circuit 1.

More specifically, as shown in (a) of FIG. 2, based on a clock serving as a reference, in order to control each of the A group, the B group, the C group, the D group, and the latch circuit LT, the control circuit 1 repeatedly performs processing of generating and outputting signals CLK_A, CLK_B, CLK_C, CLK_D, and CLK_LT in this order with a time difference, as shown in (b) of FIG. 2.

As a result, each flip-flop performs the input and output operation in response to rising edges of the signals CLK_A, CLK_B, CLK_C, and CLK_D. On the other hand, the latch circuit LT performs the input operation in response to the rising edge of the signal CLK_LT.

(b) of FIG. 2 shows signals in one cycle. The control circuit 1 repeatedly executes a cycle of sequentially outputting the signals CLK_A, CLK_B, CLK_C, CLK_D, and CLK_LT.

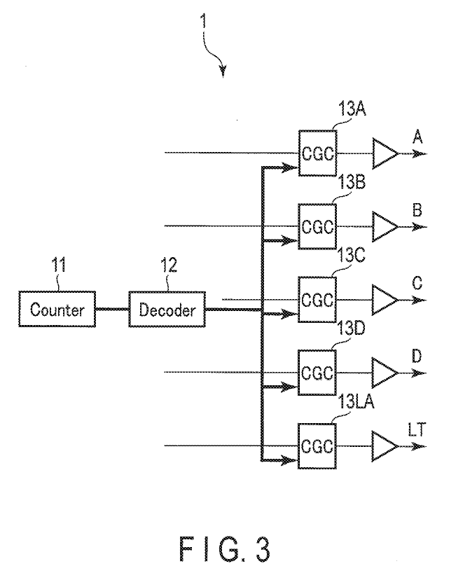

FIG. 3 is a circuit diagram showing an example of the configuration of the control circuit 1 according to the first embodiment.

The control circuit 1 is constituted of, for example, a counter 11, a decoder 12, and clock gating circuits (CGC) 13A, 13B, 13C, 13D, and 13LT.

The counter 11 repeatedly performs processing of sequentially increasing or decreasing a count value from an initial value to a predetermined value at constant time intervals.

According to the count value of the counter 11, the decoder 12 outputs data in a one-hot state (for example, bit string data with only one bit being High (value is 1)) subsequently to each of the clock gating circuits 13A, 13B, 13C, 13D, and 13LT at shifted output timings.

The clock gating circuits 13A, 13B, 13C, 13D, and 13LT receive a clock signal (the clock signal CLK described above) serving as a reference and at the same time receive the data from the decoder 12, and according to the data from the decoder 12, the clock gating circuits 13A, 13B, 13C, 13D, and 13LT output rectangular wave signals (the signals CLK_A, CLK_B, CLK_C, CLK_D, and CLK_LT described above) synchronized with this clock signal.

The circuit configuration of the control circuit 1 is not limited to the example in FIG. 3. Other circuit configurations may be used as long as they realize the same function. For example, instead of using the counter 11 and the decoder 12, data in a one-hot state may be sequentially output using a bit shifter (shift register) or the like.

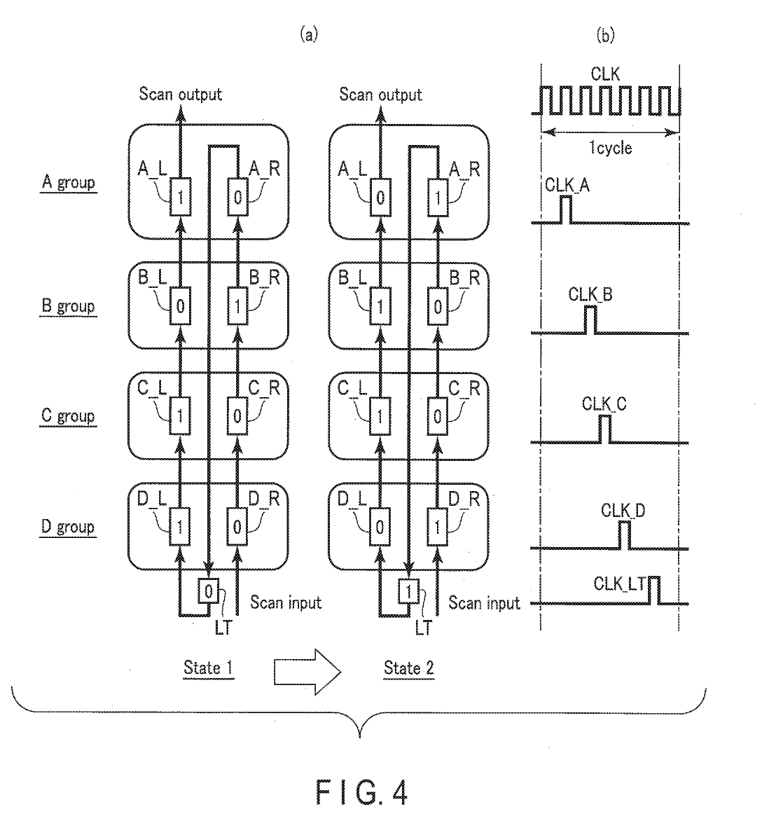

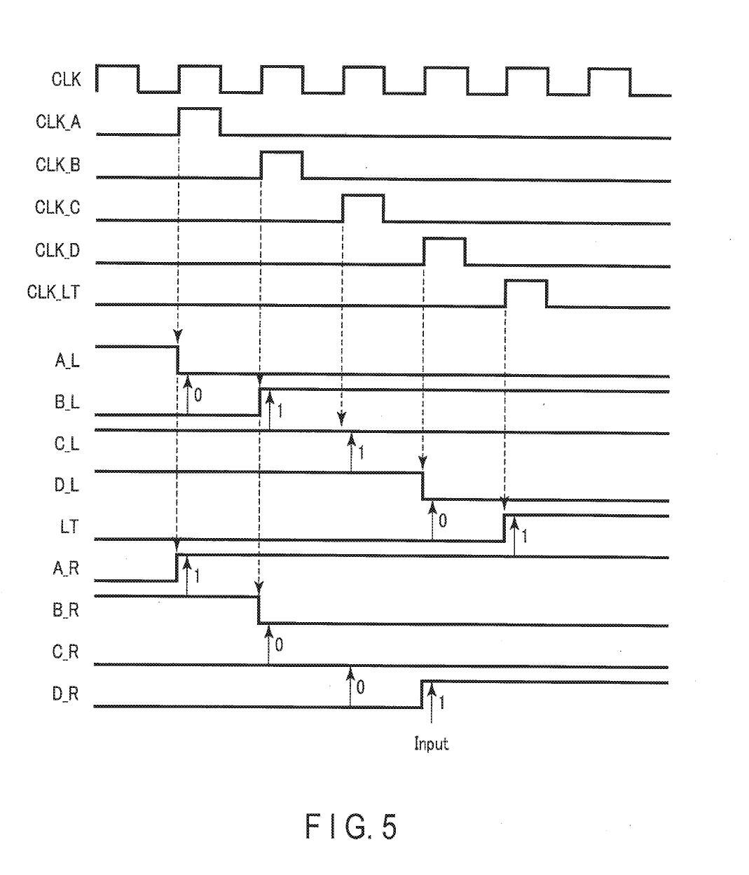

Next, an example of scan shift operation according to the first embodiment will be described with reference to FIGS. 4 and 5. In this example, the operation for one cycle will be described.

(a) of FIG. 4 shows a state where flip-flops A_L and A_R belonging to the A group, flip-flops B_L and BR belonging to the B group, flip-flops C_L and C_R belonging to the C group, flip-flops D_L and D_R belonging to the D group, and the latch circuit LT transit from a certain state 1 to the next state 2.

(b) of FIG. 4 shows a state where the signals CLK_A, CLK_B, CLK_C, CLK_D, and CLK_LT are supplied from the control circuit 1, respectively, to the A group, the B group, the C group, the D group, and the latch circuit LT during the transition from the state 1 to the state 2.

FIG. 5 shows a state where during the transition from the state 1 to the state 2, the data held by the flip-flops A_L, A_R, B_L, B_R, C_L, C_R, D_L, and D_R and the latch circuit LT are changed according to the signals CLK_A, CLK_B, CLK_C, CLK_D, and CLK_LT supplied from the control circuit 1.

In the state 1, first, the flip-flops A_L and A_R belonging to the A group perform the input and output operation in response to the rising edge of the signal CLK_A. At this time, the flip-flops A_L and A_R respectively output 1 and 0 held therein and receive 0 and 1 held in the flip-flops B_L and B_R.

Then, the flip-flops B_L and B_R belonging to the B group perform the input and output operation in response to the rising edge of the signal CLK_B. At this time, the flip-flops B_L and B_R respectively output 0 and 1 held therein and receive 1 and 0 held in the flip-flops C_L and C_R.

Then, the flip-flops C_L and C_R belonging to the C group perform the input and output operation in response to the rising edge of the signal CLK_C. At this time, the flip-flops C_L and C_R respectively output 1 and 0 held therein and receive 1 and 0 held in the flip-flops D_L and D_R.

Then, the flip-flops DL and D_R belonging to the D group perform the input and output operation in response to the rising edge of the signal CLK_D. At this time, the flip-flops D_L and D_R respectively output 1 and 0 held therein and receive a value 0 held in the latch circuit LT and a value 1 supplied from the scan input terminal side.

Finally, the latch circuit LT performs the input operation in response to the rising edge of the signal CLK_LT. At this time, the latch circuit LT receives 1 held in the flip-flop A_R. That is, the latch circuit LT holds data to be received by the flip-flop D_L (data to be transferred from the flip-flop A_R to the flip-flop D_L) in the next cycle.

By such a series of operations, the transition from the state 1 to the state 2 described above is performed. Thereafter, such operations are repeated.

According to the first embodiment, since the control circuit 1 repeats the control that makes the serially connected individual flip-flops sequentially perform the input and output operation with a time difference in a predetermined group order in units of groups and then further makes the latch circuit LT perform the input operation with a time difference, it is possible to prevent occurrence of violation of the hold time of transmission data.

### Second Embodiment

Next, the second embodiment will be described. In the following, explanations of portions common to the first embodiment will be omitted, and different portions will be mainly explained.

A schematic configuration when conducting a scan test of a semiconductor integrated circuit according to the second embodiment is similar to the case of the first embodiment, and it is as shown in FIG. 1.

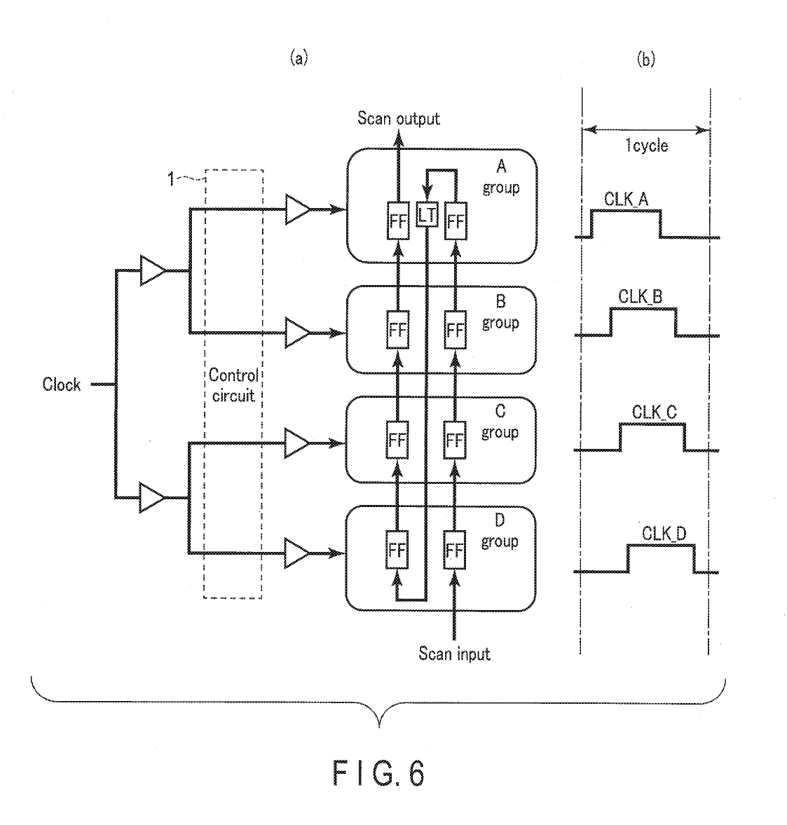

FIG. 6 is a schematic diagram for explaining an example of a circuit configuration and clock control when conducting the scan test of the semiconductor integrated circuit according to the second embodiment.

In the second embodiment, as shown in (a) of FIG. 6, it is assumed that the latch circuit LT is configured to belong to a specific group (the A group in this example) of the A group, the B group, the C group, and the D group. In this case, the control circuit 1 does not need to separately supply rectangular wave signals, having different operation timings from the A group, the B group, the C group, and the D group, only for the latch circuit LT.

The control circuit 1 may sequentially supply the rectangular wave signals to the A group, the B group, the C group, and the D group. However, the form of the rectangular wave signal output to at least the A group (for example, a time interval from the rising edge to the falling edge) is different from that in the first embodiment.

While each of the flip-flops performs the input and output operation in response to a first edge (the rising edge in this example) of the rectangular wave supplied from the control circuit 1, the latch circuit LT performs the input operation in response to a second edge (the falling edge in this example) following the first edge of the rectangular wave supplied from the control circuit 1.

More specifically, as shown in (a) of FIG. 6, based on a clock serving as a reference, in order to control each of the A group, the B group, the C group, and the D group, the control circuit 1 repeatedly performs processing of generating and outputting signals CLK_A, CLK_B, CLK_C, and CLK_D in this order with a time difference, as shown in (b) of FIG. 6.

As a result, each flip-flop performs the input and output operation in response to rising edges of the signals CLK_A, CLK_B, CLK_C, and CLK_D. On the other hand, the latch circuit LT performs the input operation in response to the falling edge of the signal CLK_A.

(b) of FIG. 6 shows signals in one cycle. The control circuit 1 repeatedly executes a cycle of sequentially outputting the signals CLK_A, CLK_B, CLK_C, and CLK_D.

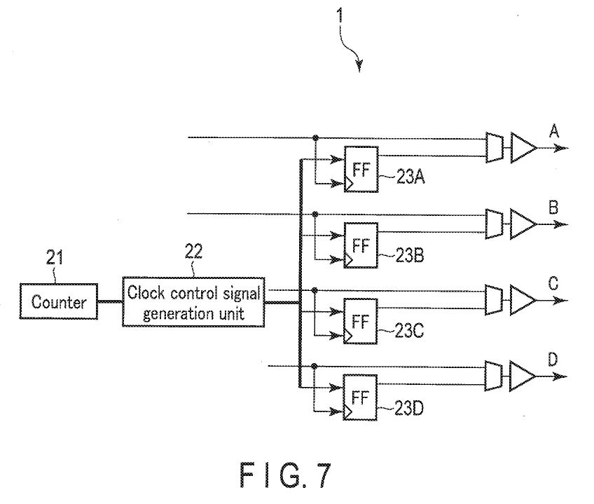

FIG. 7 is a circuit diagram showing an example of the configuration of the control circuit 1 according to the second embodiment.

The control circuit 1 is constituted of, for example, a counter 21, a clock control signal generation unit 22, flip-flops 23A, 23B, 23C, and 23D, and so on.

The counter 21 repeatedly performs processing of sequentially increasing or decreasing a count value from an initial value to a predetermined value at constant time intervals. For example, the counter 21 repeatedly performs processing of increasing the count value from 0 to 15.

According to the count value of the counter 21, the clock control signal generation unit 22 sequentially outputs data that is High (value is 1) only for a certain period of time, for example, to each of the flip-flops 23A, 23B, 23C, and 23D at shifted output timings. For example, the clock control signal generation unit 22 outputs a value of 1 to the flip-flop 23A only for a period of time during which the count value is from 1 to 7, outputs the value of 1 to the flip-flop 23B only for a period of time during which the count value is from 2 to 8, outputs the value of 1 to the flip-flop 23C only for a period of time during which the count value is from 3 to 9, and outputs the value of 1 to the flip-flop 23D only for a period of time during which the count value is from 4 to 10.

The flip-flops 23A, 23B, 23C, and 23D receive a clock signal (the clock signal CLK described above) serving as a reference and at the same time receive the data from the clock control signal generation unit 22, and according to the data from the clock control signal generation unit 22, the flip-flops 23A, 23B, 23C, and 23D output rectangular wave signals (the signals CLK_A, CLK_B, CLK_C, and CLK_D described above) synchronized with this clock signal.

The circuit configuration of the control circuit 1 is not limited to the example in FIG. 7. Other circuit configurations may be used as long as they realize the same function.

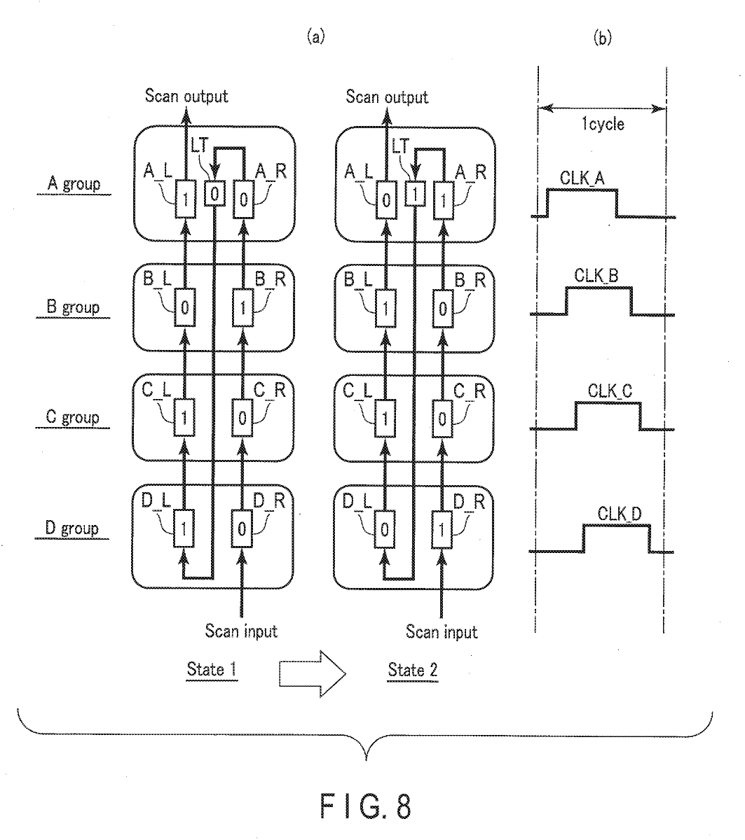

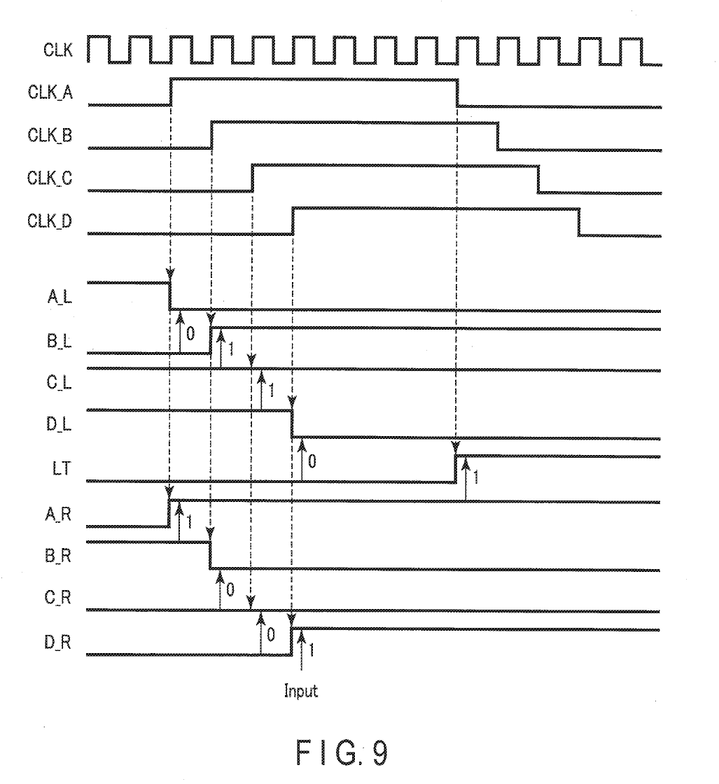

Next, an example of scan shift operation according to the second embodiment will be described with reference to FIGS. 8 and 9. In this example, the operation for one cycle will be described.

(a) of FIG. 8 shows a state where flip-flops A_L and A_R and the latch circuit LT belonging to the A group, flip-flops B_L and B_R belonging to the B group, flip-flops C_L and C_R belonging to the C group, and flip-flops D_L and D_R belonging to the D group transit from a certain state 1 to the next state 2.

(b) of FIG. 8 shows a state where the signals CLK_A, CLK_B, CLK_C, and CLK_D are supplied from the control circuit 1, respectively, to the A group, the B group, the C group, and the D group during the transition from the state 1 to the state 2.

FIG. 9 shows a state where during the transition from the state 1 to the state 2, the data held by the flip-flops A_L, A_R, B_L, B_R, C_L, C_R, D_L, and D_R and the latch circuit LT are changed according to the signals CLK_A, CLK_B, CLK_C, and CLK_D supplied from the control circuit 1.

In the state 1, first, the flip-flops A_L and A_R belonging to the A group perform the input and output operation in response to the rising edge of the signal CLK_A. At this time, the flip-flops A_L and A_R respectively output 1 and 0 held therein and receive 0 and 1 held in the flip-flops B_L and B_R.

Then, the flip-flops B_L and B_R belonging to the B group perform the input and output operation in response to the rising edge of the signal CLK_B. At this time, the flip-flops B_L and B_R respectively output 0 and 1 held therein and receive 1 and 0 held in the flip-flops C_L and C_R.

Then, the flip-flops C_L and C_R belonging to the C group perform the input and output operation in response to the rising edge of the signal CLK_C. At this time, the flip-flops C_L and C_R respectively output 1 and 0 held therein and receive 1 and 0 held in the flip-flops D_L and D_R.

Then, the flip-flops D_L and D_R belonging to the D group perform the input and output operation in response to the rising edge of the signal CLK_D. At this time, the flip-flops D_L and DR respectively output 1 and 0 held therein and receive a value 0 held in the latch circuit LT and a value 1 supplied from the scan input terminal side.

Finally, the latch circuit LT performs the input operation in response to the falling edge of the signal CLK_A. At this time, the latch circuit LT receives 1 held in the flip-flop A_R. That is, the latch circuit LT holds data to be received by the flip-flop D_L (data to be transferred from the flip-flop A_R to the flip-flop D_L) in the next cycle.

By such a series of operations, the transition from the state 1 to the state 2 described above is performed. Thereafter, such operations are repeated.

According to the second embodiment, in addition to the effect obtained in the first embodiment, since the control circuit 1 does not need to separately supply rectangular wave signals, having different operation timings from the A group, the B group, the C group, and the D group, only for the latch circuit LT, it is possible to obtain the effect of eliminating wiring therefor.

### Third Embodiment

Next, the third embodiment will be described. In the following, explanations of portions common to the first and second embodiments will be omitted, and different portions will be mainly explained.

In the third embodiment, a method of designing the semiconductor integrated circuit described in the first and second embodiments will be described.

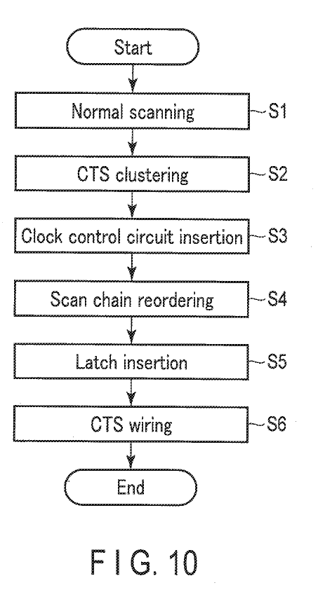

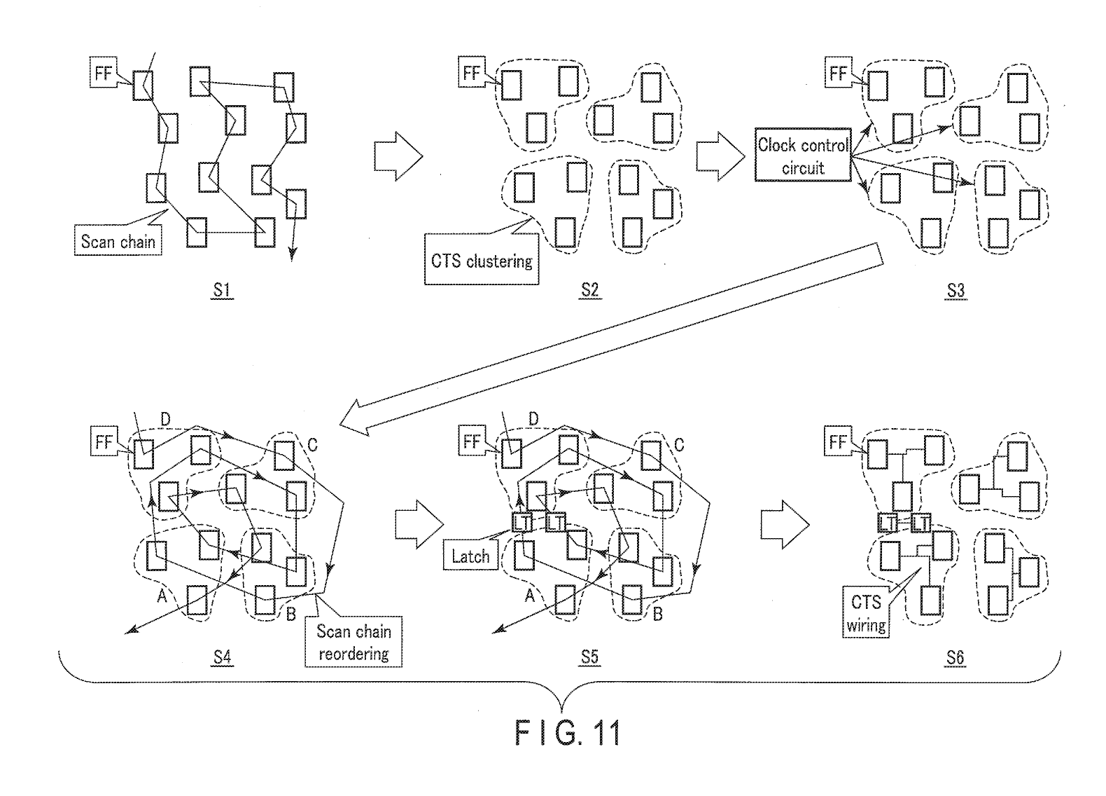

FIG. 10 is a flowchart showing the design procedure of a semiconductor integrated circuit according to the third embodiment. FIG. 11 is a schematic diagram showing processing contents of individual steps shown in FIG. 10. Hereinafter, an example of the design procedure of the semiconductor integrated circuit will be described with reference to FIGS. 10 and 11.

First, ordinary scanning is performed on a plurality of flip-flops included in the semiconductor integrated circuit (S1 in FIG. 10). In this case, as shown in S1 in FIG. 11, for example, individual flip-flops (FF) are serially connected in a scan chain according to a predetermined rule.

Next, clock tree synthesis (CTS) clustering is performed on the flip-flops connected in the scan chain (S2 in FIG. 10). In this case, as shown in S2 in FIG. 11, for example, the flip-flops are grouped by CTS clustering.

Then, a clock control circuit (corresponding to the control circuit 1 in the first or second embodiment) is inserted (S3 in FIG. 10). In this case, as shown in S3 in FIG. 11, for example, a clock control circuit individually controlling individual groups formed by CTS clustering is inserted.

Then, scan chain reordering is performed on the grouped flip-flops (S4 in FIG. 10). In this case, as shown in S4 in FIG. 11, for example, a scan chain is reconstructed such that data is circulated and transmitted plural times in a predetermined group order (in the order of groups D, C, B, and A in this example).

Then, latch insertion is performed (S5 in FIG. 10). In this case, as shown in S5 in FIG. 11, for example, a latch circuit (corresponding to the latch circuit LT in the first or second embodiment) temporarily holding data transferred between specific groups (data transferred from the A group to the D group in this example) is inserted. The latch circuit at this time may be disposed so as not to belong to any group as illustrated or so as to belong to, for example, the A group.

Finally, a CTS wiring is formed (S6 in FIG. 10). In this case, as shown in S6 in FIG. 11, for example, the CTS wiring connecting a plurality of flip-flops in individual groups is formed.

After the semiconductor integrated circuit is fabricated through such a design, a scan test is performed on the semiconductor integrated circuit, and the scan shaft operation is realized by the control as described in the first or second embodiment, for example.

The design procedure of the semiconductor integrated circuit is not limited to the examples of FIGS. 10 and 11. As long as there is no hindrance, the processing order of some steps may be changed and executed. For example, S4 and S5 may be replaced with each other.

According to the third embodiment, it is possible to advance the design of the semiconductor integrated circuit without worrying about the occurrence of violation of the hold time of transmission data, so that an effect capable of reducing the time required for examination work and the like and shortening the design period can be obtained.

As described in detail above, according to the embodiments, it is possible to prevent occurrence of violation of the hold time of transmission data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made. The accompanying claims and their equivalents are intended to cover such forms or modifications as would fall within the scope of the inventions.

1. An integrated circuit comprising:
a plurality of flip-flops; and
a control circuit that repeats a control that makes each of the flip-flops perform input and output operation in a predetermined group order with a time difference in a state where the flip-flops are connected in a scan chain and grouped.

2. The integrated circuit according to claim 1, wherein:
the control circuit repeatedly performs processing of supplying a rectangular wave signal to each group with a time difference in a predetermined group order, and
each of the flip-flops sequentially performs the input and output operation in response to a first edge of a rectangular wave supplied from the control circuit.

3. The integrated circuit according to claim 1, further comprising a data holding circuit that temporarily holds data transferred between specific groups.

4. The integrated circuit according to claim 3, wherein the control circuit makes each of the flip-flops sequentially perform the input and output operation in a predetermined group order with a time difference and then further makes the data holding circuit perform input operation with a time difference.

5. The integrated circuit according to claim 3, wherein:
the data holding circuit is configured not to belong to any group,
the control circuit supplies a rectangular wave signal to each group in a predetermined group order with a time difference and then further supplies the rectangular wave signal to the data holding circuit with a time difference, and
the data holding circuit performs input operation in response to a first edge of a rectangular wave supplied from the control circuit.

6. The integrated circuit according to claim 3, wherein:
the data holding circuit is configured to belong to a specific group, and
the data holding circuit performs input operation in response to a second edge following a first edge of a rectangular wave supplied from the control circuit to the specific group.

7. The integrated circuit according to claim 3, wherein the data holding circuit is realized by a latch circuit that holds data of 1 bit.

8. A scan shift control method comprising:
connecting a plurality of flip-flops in series in a scan chain and grouping the flip-flops; and
repeating a control that makes each of the flip-flops perform input and output operation in a predetermined group order with a time difference by a control circuit.

9. The scan shift control method according to claim 8, further comprising:
repeatedly performing processing of supplying a rectangular wave signal to each group in a predetermined group order with a time difference by the control circuit; and
making each of the flip-flops sequentially perform the input and output operation in response to a first edge of a rectangular wave supplied from the control circuit.

10. The scan shift control method according to claim 8, further comprising making a data holding circuit temporarily hold data transferred between specific groups.

11. The scan shift control method according to claim 10, further comprising making each of the flip-flops sequentially perform the input and output operation in a predetermined group order with a time difference by the control method and then further making the data holding circuit perform input operation with a time difference.

12. The scan shift control method according to claim 10, further comprising:
configuring the data holding circuit such that the data holding circuit does not belong to any group;
by the control circuit, supplying a rectangular wave signal to each group in a predetermined group order with a time difference and then further supplying the rectangular wave signal to the data holding circuit with a time difference; and
making the data holding circuit perform input operation in response to a first edge of a rectangular wave supplied from the control circuit.

13. The scan shift control method according to claim 10, further comprising:
configuring the data holding circuit such that the data holding circuit belongs to a specific group; and
making the data holding circuit perform input operation in response to a second edge following a first edge of a rectangular wave supplied from the control circuit to the specific group.

14. The scan shift control method according to claim 10, comprising realizing the data holding circuit by a latch circuit that holds data of 1 bit.

15. A circuit design method comprising:
connecting a plurality of flip-flops, included in an integrated circuit, in series in a scan chain;
grouping the flip-flops; and
providing a circuit configured to make each of the flip-flops perform input and output operation in a predetermined group order with a time difference.
